(19) United States
(12) Patent Application Publication
(10) Pub. No.: US 2010/0224250 A1
(43) Pub. Date: Sep. 9, 2010

(54) Solar cell device structure

(76) Inventors: Hwen-Fen Hong, Longtan Township (TW); Yueh-Mu Lee, Longtan Township (TW); Shang-Yu Tsai, Longtan Township (TW); Cherng-Tsong Kuo, Longtan Township (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 12/453,750

(22) Filed: May 21, 2009

(30) Foreign Application Priority Data
Mar. 6, 2009 (TW) 098107389

(51) Int. Cl. H01L 31/00

(52) U.S. Cl. 136/261

(57) ABSTRACT

A solar cell device structure, that is applicable in a concentrator solar cell device structure, comprising a silicon substrate, an insulation layer, and a solar chip. Wherein, the insulation layer is provided on the silicon substrate, a pattern region is provided on the insulation layer, and the solar chip is disposed in the pattern region. Due to the various advantages of superior heat conduction, low cost, and maturity of silicon semiconductor manufacturing technology of a silicon substrate, it is utilized to replace the ceramic substrate of the prior art, hereby raising the heat dissipation efficiency and reducing the production cost.

### BACKGROUND OF THE INVENTION

1. Field of the Invention

The present invention relates to a solar cell device structure, and in particular to a solar cell (photovoltaic cell) device structure capable of raising its heat dissipation efficiency by making use of a silicon substrate.

2. The Prior Arts

In recent years, along with the rapid progress and improvements of living standard, the demand of energy consumption has been increasing rapidly. However, since the traditional energy resources on earth are drained nearly to their depletion, so that in this situation, various re-generable energy resources are developed to meet the energy requirements. Among them, solar energy is most prominent and important one, and is getting most of the attention. In general, solar-energy-electricity-generation is realized through a kind of solar cell made of semiconductor materials, thus converting solar energy into electrical energy.

For a more advanced model solar cell, a concentrator solar cell (photovoltaic cell) device structure is taken as an example for explanation. Basically, it is quite different from a traditional panel solar cell device structure mainly in that, it is a solar cell made of multi-junction group III-V compound semiconductor having an advantage of superior heat-resistance, and it can achieve 40.7% photo-to-electrical-energy conversion efficiency under a concentration ratio of several-hundred. However, in proceeding with photo-to-electrical-energy conversion utilizing a concentrator solar cell, due to the restrictions of light absorption capability of the material utilized to a certain section of spectrum, thus the input optical energy can not be converted to output electrical energy in its entirety. As such, the remaining portions of the solar energy that enters into a solar cell will either be reflected or transmitted, or it will remain and be accumulated in the solar cell in a form of heat energy, hereby causing an increase of temperature of the solar cell device structure. Though temperature increase will cause an increase of possibility of carrier generation; yet, in contrast, the increase of temperature will cause a significant increase of dark current inside a solar cell, and that would in turn reduce the efficiency of conversion from solar energy to electrical energy.

Refer to FIG. 1 for a cross section view of a solar cell device structure according to the prior art. As shown in FIG. 1, the solar cell device structure includes a ceramic substrate 11, a circuit layout layer 12 disposed on the ceramic substrate 11, and a layer of solar cell 13 formed on the circuit layout layer 12. Wherein, ceramic substrate 11 is utilized as a carrier substrate for a solar cell 13, and when in operation, it may also function as a heat dissipation substrate for the heat of high temperature thus generated. Thus, upon absorbing solar energy by the solar cell 13 and converting it into electrical energy, the electrical energy thus generated will be transferred by the circuit layout layer 12 into a storage unit. Since significant heat of high temperature will be generated while solar cell 13 and circuit layout layer 12 are in operation, yet, the inferior heat conduction capacity of a ceramic substrate 11 is not sufficient to transfer the heat thus generated properly into the outside air, hereby resulting in inferior photo-to-electrical-energy conversion efficiency. Therefore, in order to alleviate and solve the heat dissipation problem, a heat dissipation fin 14 or a heat dissipation aluminum plate is placed below the ceramic substrate 11 to enhance its heat dissipation efficiency. However, by doing so, not only the complexity of manufacturing processes is increased, but the production cost is also raised.

For the reasons mentioned above, it is evident that the functions and performances of solar cell of the prior art are not quite satisfactory, thus it has much room for improvements.

### SUMMARY OF THE INVENTION

In view of the shortcomings and drawbacks of the prior art, the present invention discloses a solar cell device structure, so as to solve the afore-mentioned problems of the prior art.

A major objective of the present invention is to provide a solar cell device structure, wherein, silicon substrate is utilized as a carrier substrate for a solar cell, and it is also utilized as a heat dissipation substrate for dissipating the heat of high temperature generated during operation by making use of merits and advantages of silicon substrate: superior heat conduction capability, low production cost, and maturity of semiconductor manufacturing technology for silicon, thus raising its heat dissipation capability and efficiency.

Another objective of the present invention is to provide a silicon substrate of heat conductivity of 124 W/m·K utilized in producing concentrator solar cell device structure, that is a considerable improvement over the ceramic substrate of heat conductivity of 30 W/m·K of the prior art having the shortcomings that, heat is liable to accumulate in the substrate, thus reducing the photo-to-electrical-energy conversion efficiency of the solar cell thus produced.

A yet another objective of the present invention is to provide a silicon substrate used for manufacturing solar cell device structure, and that is used to replace the ceramic substrate of the prior art, so as to solve the shortcomings of inferior heat dissipation efficiency of ceramic substrate, since that could incur the problems of having to install additional heat dissipating plates, hence increasing the complexity of manufacturing processes and raising the production cost.

To achieve the afore-mentioned objective, the present invention discloses a solar cell device structure, including: a silicon substrate, an insulation layer, and a solar chip. Wherein, the insulation layer is disposed on the silicon substrate, and the insulation layer is provided with a pattern region thereon, and the solar chip is connected to the pattern region through a heat-conduction & electricity-conduction adhesion layer.

Further scope of the applicability of the present invention will become apparent from the detailed description given hereinafter. However, it should be understood that the detailed description and specific examples, while indicating preferred embodiments of the present invention, are given by way of illustration only, since various changes and modifications within the spirit and scope of the present invention will become apparent to those skilled in the art from this detailed description.

### BRIEF DESCRIPTION OF THE DRAWINGS

The related drawings in connection with the detailed description of the present invention to be made later are described briefly as follows, in which:

FIG. 1 is a cross section view of a solar cell device structure according to the prior art;

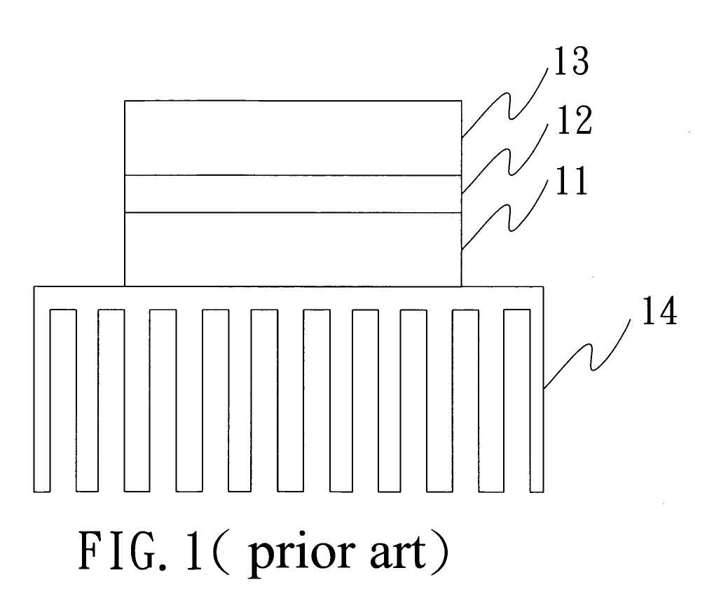

FIG. 2 is a perspective view of a solar cell device structure according to an embodiment of the present invention; and

FIG. 3 is a cross section view of a solar cell device structure according to according to an embodiment of the present invention.

### DETAILED DESCRIPTION OF THE PREFERRED EMBODIMENT

The purpose, construction, features, functions, and advantages of the present invention can be appreciated and understood more thoroughly through the following detailed description with reference to the attached drawings.

In the following, please refer to the related drawings together with detailed descriptions in describing a solar cell device structure according to an embodiment of the present invention. For easy reference and understanding, similar reference numerals are utilized to refer to similar elements.

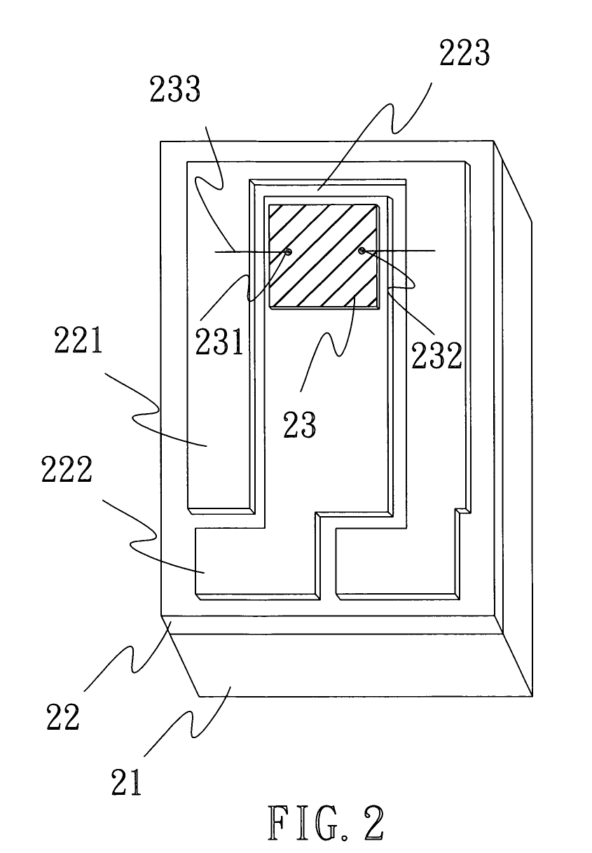

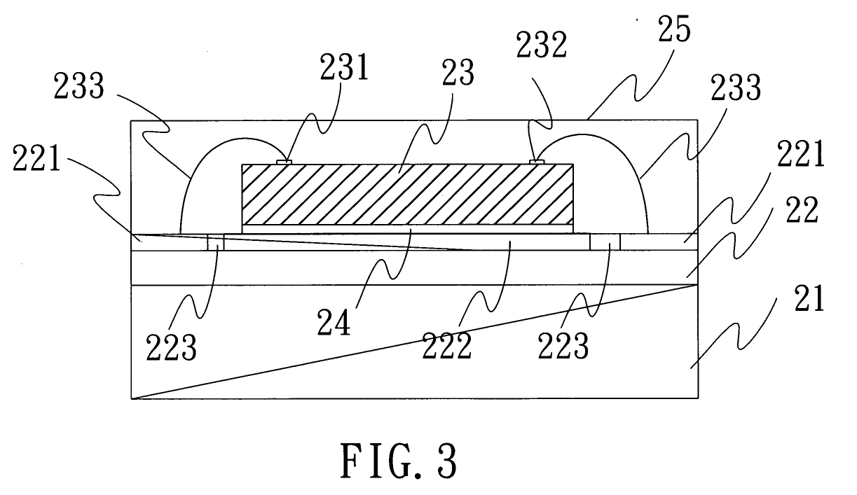

In the following descriptions, please refer to FIGS. 2 & 3 simultaneously. Wherein, FIG. 2 is a perspective view of solar cell device structure according to an embodiment of the present invention; and FIG. 3 is a cross section view of a solar cell device structure according to an embodiment of the present invention. As shown in FIGS. 2 & 3, the solar cell device structure of the present invention is applicable to a concentrator solar cell device structure. Wherein, a solar cell device structure includes: a silicon substrate 21, an insulation layer 22, and a solar chip 23.

In the above-mentioned structure, the insulation layer 22 is disposed on the silicon substrate 21, and a pattern region is provided on the insulation layer 22. The pattern region is a kind of patterned metal layer, that is formed on the insulation layer 22 by means of vaporizing, sputtering, plating, or chemical vapor deposition (CVD). The pattern region includes a first conduction portion 221 and a second conduction portion 222, such that an insulation layer 223 is disposed between the first conduction portion 221 and the second conduction portion 222. Wherein, on the second conduction portion 222 is disposed a heat-conduction & electricity-conduction adhesion layer 24 made of solder, and that is connected to a solar chip 23. The solar chip 23 includes a first electrode 231 serving as a positive electrode, and a second electrode 232 serving as a negative electrode, such that the first electrode 231 and the second electrode 232 are electrically connected to the first conduction portion 221 through at least a metal wire 233 by means of wire bonding. In this structure, a transparent silicone or low reflectivity material is covered on the solar chip 23 for serving as a protection layer 25, as shown in FIG. 3. The protection layer 25 thus formed is used to protect solar chip 23 and its first electrode 231 and second electrode 232, such that it is capable of protecting the solar chip 23 from adverse influence of interference, contamination, and moisture of outside environment. As such, when solar energy is absorbed by a solar chip 23 and is converted into electrical energy, the electrical energy thus obtained is transferred from a pattern region to a storage unit (not shown) for storage.

In the present invention, silicon substrate 21 is utilized as a carrier substrate for solar chip mainly for its advantages of superior heat conduction, low cost, and maturity of semiconductor manufacturing technology utilizing silicon as a raw material. Wherein, silicon is the most important material utilized in semiconductor industry, and it is widely utilized in enormous quantity. In general, its major source is silica sand (SiO₂), which is readily available, and is comparatively inexpensive. For this reason, the production cost of silicon substrate is lower than that of ceramic substrate of the prior art. In the present invention, silicon substrate 11 is utilized as a carrier substrate for solar chip 23, and it is also used as a heat dissipation substrate for dissipating heat of high temperature generated during the operation of solar cell device structure. Therefore, in operation, the heat of high temperature generated by solar chip 23 and pattern region will be transferred into outside air through a silicon substrate 21. Furthermore, in replacing ceramic substrate of the prior art by the silicon substrate of the present invention, the production cost can be reduced. The solar chip 23 is mainly made of group 3-5 materials, namely, the single crystal or multi-crystal material of group IIIA and VA elements or Si element in a Mendeleev periodic table, wherein, Gallium Arsenide (GaAs), Gallium Aluminum Arsenide (GaAlAs), or Indium Phosphide (InP) is preferred.

Refer to Table 1 for the heat conductivity coefficients for various substrate materials:

TABLE 1

| material | heat conductivity (W/m · K) |
|---|---|
| silicon (Si) | 124 |
| ceramic (Al₂O₃) | 30 |

Under the irradiation and concentration of light, the solar chip will absorb solar energy irradiated by the sun, while proceeding with the photo-to-electricity energy conversion, so that temperatures of solar chip and pattern region tend to increase higher along with the increase of light concentration ratio. Since in the prior art, ceramic substrate is utilized as a carrier substrate of a solar chip, and it is also utilized as a heat dissipation substrate for dissipating heat of high temperature during operation. For the reasons that heat conductivity of ceramic (Al₂O₃) substrate is merely 30 W/m·K as shown in Table 1, so that heat can not be sufficiently dissipated out into the outside air, thus degrading the photo-to-electrical-energy conversion efficiency of a solar chip.

For the reasons mentioned above, in the present invention, silicon substrate is utilized to replace the ceramic substrate of the prior art. As shown in Table 1, the silicon substrate of high heat conductivity of 124 W/m·K can be utilized to effectively transfer and dissipate the heat generated by a solar chip to the outside air, thus increasing heat dissipation efficiency of solar chip and reducing its temperature, and this will in turn increase the photo-to-electrical-energy conversion efficiency of a solar chip. In addition, the application of silicon substrate of the present invention can eliminate the necessity of having to install additional heat dissipation fins due to the inferior heat dissipation efficiency of ceramic substrate of the prior art, since that could incur the problems of increasing complexity of manufacturing processes and production cost.

The above detailed description of the preferred embodiment is intended to describe more clearly the characteristics and spirit of the present invention. However, the preferred embodiments disclosed above are not intended to be any restrictions to the scope of the present invention. Conversely, its purpose is to include the various changes and equivalent arrangements which are within the scope of the appended claims.

What is claimed is:

1. A solar cell device structure, comprising:
a silicon substrate;
an insulation layer, disposed on said silicon substrate, and a pattern region is provided on said insulation layer; and
a solar chip, disposed in said pattern region.

2. The solar cell device structure as claimed in claim 1, wherein
a heat conductivity of said silicon substrate is 124 W/m·K.

3. The solar cell device structure as claimed in claim 1, wherein
said insulation layer is made of silicon dioxide (SiO₂).

4. The solar cell device structure as claimed in claim 1, wherein
said pattern region includes a first conduction portion and a second conduction portion, and an insulation portion is provided between said first conduction portion and said second conduction portion.

5. The solar cell device structure as claimed in claim 4, wherein
said solar chip includes a first electrode and a second electrode, and said first electrode and said second electrode is electrically connected to said first conduction portion through at least a metallic wire.

6. The solar cell device structure as claimed in claim 4, wherein
said second conduction portion is provided with a heat-conduction & electricity-conduction adhesion layer connected to said solar chip.

7. The solar cell device structure as claimed in claim 6, wherein
said heat-conduction & electricity-conduction adhesion layer is made of a solder past.

8. The solar cell device structure as claimed in claim 1, wherein
said patterned region is a patterned metal layer, and is formed on said insulation layer by means of vaporizing, sputtering, plating, or chemical vapor deposition (CVD).
